(19) United States
(12) Patent Application Publication
(10) Pub. No.: US 2011/0284949 A1
(43) Pub. Date: Nov. 24, 2011

(54) VERTICAL TRANSISTOR AND A METHOD OF FABRICATING THE SAME

(75) Inventors: Hsin-Fei Meng, Hsinchu (TW); Hsiao-Wen Zan, Hsinchu (TW); Yu-Chiang Chao, Hsinchu (TW)

(73) Assignee: National Chiao Tung University, Hsinchu (TW)

(21) Appl. No.: 12/786,343

(22) Filed: May 24, 2010

(51) Int. Cl. H01L 29/78; H01L 21/336

(52) U.S. Cl. 257/329; 438/268; 438/138; 257/133; 257/E29.262; 257/E21.41

(57) ABSTRACT

A vertical transistor and a method of fabricating the vertical transistor are provided. The vertical transistor has a substrate, a first electrode formed on the substrate, a first insulation layer formed on the first electrode, with a portion of the first electrode exposed from the first insulation layer and having a thickness greater than 50 nm and no more than 300 nm, a grid electrode formed on the first insulation layer, a semiconductor layer formed on the first electrode, and a second electrode formed on the semiconductor layer.

### BACKGROUND OF THE INVENTION

1. Field of the Invention

This invention relates to vertical transistors, and more particularly, to an organic vertical transistor having a vertical structure.

2. Description of Related Art

With the rapid development of technology, lighter, thinner, portable and flexible displays, such as electronic paper, have drawn people's attention. Accordingly, many well-known companies invest a lot of money in the development of the displays. An organic thin-film vertical transistor (OTFT) includes organic molecules and is applied to electronic products. The organic thin-film vertical transistor may be fabricated in a low temperature environment, and still function normally even if the panel bends. Such an application speeds up the realization of a flexible electronic product (e.g., a display).

An organic thin-film vertical transistor has various advantages, such as low carrier channel length, which allows it to be applied to high-frequency components, and low working bias voltage.

In order to reduce a distance between the source electrode and the drain electrode, N. Stutzmann et al. (2003) Science 299, 1881, R. Parashkov et al. (2003) Appl. Phys. Lett. 82, 4579 and R. Parashkov et al. (2004) Appl. Phys. Lett. 85, 5751 disclose separating the source electrode from the drain electrode with an insulation layer, so as to control the distance between the source electrode and the drain electrode. The method uses a mechanical or chemical process to form grooves on the insulation layer, and then form a carrier transmission channel in the grooves. However, the method includes complicated steps, and the components fabricated thereby do not perform well.

M. S. Meruvia et al. (2004) Appl. Phys. Lett. 84, 3978, W. J. da Silva et al. (2008) Appl. Phys. Lett. 93, 053301, and M. Yi et al. (2008) Appl. Phys. Lett. 92, 243312 disclose using silicon as a collector electrode. Y. C. Chao et al. (2005) Appl. Phys. Lett. 87, 253508, and Y. C. Chao et al. (2008) Appl. Phys. Lett. 92, 093310 disclose a component that does not have a high enough on/off ratio.

Y. Yang et al. (1994) Nature 372, 344, J. McElvain, et al. (1997) J. Appl. Phys. 81, 6468, and U.S. Pat. No. 5,563,424 disclose separating three electrode with two organic molecule layers. However, the method needs to perform a chemical process on the second electrode, which complicates the fabrication steps and limits the selection of organic molecule materials.

Y. C. Chao et al. (2006) Appl. Phys. Lett. 87, 223505 and Y. C. Chao et al. (2008) Organic Electronics 9, 310 disclose a method of fabricating a vertical transistor by using polystyrene balls as a mask. However, the polystyrene balls are disposed on a semiconductor polymer layer, and the semiconductor polymer layer has to have its characteristics unaffected, which limits the selection of the semiconductor polymer layer material. Moreover, no insulation layer is formed between a gate electrode and the other two electrodes, which likely induces the leakage current.

Please refer to FIG. 1, which shows a vertical transistor 1 disclosed in US Patent Application Publication No. 2009/0042142, including a substrate 10, a first electrode 11 formed on the substrate 10, a first insulation layer 12 formed on a portion of the first electrode 11, a gate electrode 14 formed on the first insulation layer 12, a second insulation layer 15 formed on the gate electrode 14, a lateral insulation layer 18 formed on a lateral of the first insulation layer 12, the gate electrode 14 and the second insulation layer 15, a semiconductor layer 16 formed on the first electrode 11 and the second insulation layer 15, and a second electrode 17 formed on the semiconductor layer 16. The first insulation layer 12 and the second insulation layer 15 preferably have a thickness being 5-50 nm, but have worse performance while being thicker.

However, persons skilled in the art are unable to increase an on/off ratio of the vertical transistor through the above thickness teaching, and obtain a better performance.

Therefore, it is an urgent issue to overcome the problems of an organic thin-film vertical transistor having a vertical structure in the prior art.

### SUMMARY OF THE INVENTION

In view of the above-mentioned problems of the prior art, the present invention provides, in a first aspect, a vertical transistor that includes a substrate, a first electrode formed on the substrate, a first insulation layer formed on the first electrode, with a portion of the first electrode exposed from the first insulation layer, and having a thickness greater than 50 nm and no more than 300 nm, a grid electrode formed on the first insulation layer, a semiconductor layer formed on the first electrode, and a second electrode formed on the semiconductor layer.

In the aforesaid vertical transistor, the semiconductor layer is further formed on the grid electrode, and the second electrode is positioned not in correspondence with the grid electrode.

The present invention provides, in a second aspect, a vertical transistor that includes a substrate, a first electrode formed on the substrate with a portion of a surface of the substrate exposed from the first electrode, a first insulation layer formed on the exposed portion of the surface of the substrate and higher than first electrode, a grid electrode formed on the first insulation layer, a semiconductor layer formed on the grid electrode and the first electrode, and a second electrode formed on the semiconductor layer.

The present invention provides, in a third aspect, a vertical transistor that includes a substrate, a first insulation layer formed on the substrate and having a plurality of grooves formed thereon, a first electrode formed in the grooves and having a height less than a depth of the grooves, a grid electrode formed on the first insulation layer and being positioned not in correspondence with the first electrode, a semiconductor layer formed on the grid electrode and the first electrode, and a second electrode formed on the semiconductor layer.

The aforesaid vertical transistors may further include a second insulation layer formed between the grid electrode and the semiconductor layer, and the first insulation layer and the second insulation layer may include the same material.

The present invention provides, in a fourth aspect, a method of fabricating a vertical transistor including the steps of providing substrate, forming on the substrate a first electrode and a first insulation layer sequentially, forming the patterned grid electrode on the first insulation layer, removing a portion of the first insulation layer on which the grid electrode is not formed by using the grid electrode as a mask so as to expose a portion of the first electrode, covering the grid electrode and the first electrode with a semiconductor layer, and forming a second electrode on the semiconductor layer.

In the fourth aspect of the method, the step of forming the patterned grid electrode includes forming on the first insulation layer a plurality of balls spaced apart at intervals, forming a metal layer on the intervals at which the balls are spaced apart on a portion of the first insulation layer, and removing the balls so as to allow the metal layer to be the grid electrode.

In the fourth aspect of the method, the step of forming the patterned grid electrode includes forming on the first insulation layer a resist layer having a plurality of holes for exposing a portion of the first insulation layer, forming a metal layer on the exposed portion of the first insulation layer, and removing the resist layer, so as to allow the metal layer to be the grid electrode.

In the fourth aspect of the method, the step of forming the patterned grid electrode includes forming a metal layer on the first insulation layer, forming on the metal layer a resist layer having a plurality of holes for exposing a portion of the metal layer, removing the exposed portion of the metal layer, and removing the resist layer, so as to allow the remaining metal layer to be the grid electrode.

The aforesaid method further includes the step of forming a second insulation layer on the grid electrode.

The present invention provides, in a fifth aspect, a method of fabricating a vertical transistor including the steps of providing a substrate, forming a first electrode on the substrate, forming on the first electrode a first insulation layer, a metal layer, and a second insulation layer, pattering the first insulation layer, the metal layer, and the second insulation layer to allow the metal layer to form a grid electrode and expose a portion of the first electrode, forming on the exposed portion of the first electrode a semiconductor layer that is at a position higher than the grid electrode, and forming on the semiconductor layer a second electrode that is positioned not in correspondence with the grid electrode.

The present invention provides, in a sixth aspect, a method of fabricating a vertical transistor including the steps of providing a substrate, forming a first electrode on the substrate, forming on the first electrode a resist layer having a plurality of holes for exposing a portion of the first electrode, forming in the holes a first insulation layer and a metal layer sequentially, removing the resist layer to allow the metal layer to act as a grid electrode, forming a semiconductor layer on the grid electrode and the first electrode, and forming a second electrode on the semiconductor layer.

In the sixth aspect, the method further includes prior to forming the first insulation layer, removing the exposed portion of the first electrode so as to expose a portion of a surface of the substrate, wherein the first insulation layer and the metal layer are formed sequentially on the exposed portion of the surface of the substrate, and the first insulation layer is at a position higher than the first electrode.

In the sixth aspect, the method further includes prior to removing the resist layer, forming a second insulation layer on the metal layer.

The present invention provides, in a seventh aspect, a method of fabricating a vertical transistor including the steps of providing a substrate, forming on the substrate a first insulation layer having a plurality of grooves, forming a metal layer on the first insulation layer, wherein the metal layer in the grooves serves as a first electrode, the metal layer not in the grooves serves as a grid electrode, and the first electrode has a height less than a depth of the grooves, forming a semiconductor layer on the first electrode and the grid electrode, and forming a second electrode on the semiconductor layer.

In the seventh aspect, the method further includes prior to forming the semiconductor layer, forming a second insulation layer on the grid electrode.

### BRIEF DESCRIPTION OF DRAWINGS

The invention can be more fully understood by reading the following detailed description of the preferred embodiments, with reference made to the accompanying drawings, wherein:

FIG. 1 is a schematic diagram of a vertical transistor according to the prior art;

FIGS. 2A-2F″ are schematic diagrams illustrating a method of fabricating a vertical transistor of a first embodiment according to the present invention, wherein FIGS. 2F′ and 2F″ show other variants;

FIGS. 3A-3D′ are schematic diagrams illustrating a method of fabricating a vertical transistor of a second embodiment according to the present invention, wherein FIGS. 3A′-3D′ are schematic diagrams illustrating a modified method of fabricating a vertical transistor;

FIGS. 4A-4E are schematic diagrams illustrating a method of fabricating a vertical transistor of a third embodiment according to the present invention, and FIGS. 4A′-4D′ are schematic diagrams illustrating a modified method of fabricating a vertical transistor;

FIGS. 5A-5F are schematic diagrams illustrating a method of fabricating a vertical transistor of a fourth embodiment according to the present invention, and FIG. 5F′ is a schematic diagram showing a vertical transistor of a variant embodiment; and

FIGS. 6A-6C are schematic diagrams illustrating a method of fabricating a vertical transistor of a fifth embodiment according to the present invention, and FIG. 6C′ is a schematic diagram showing a vertical transistor of a variant embodiment.

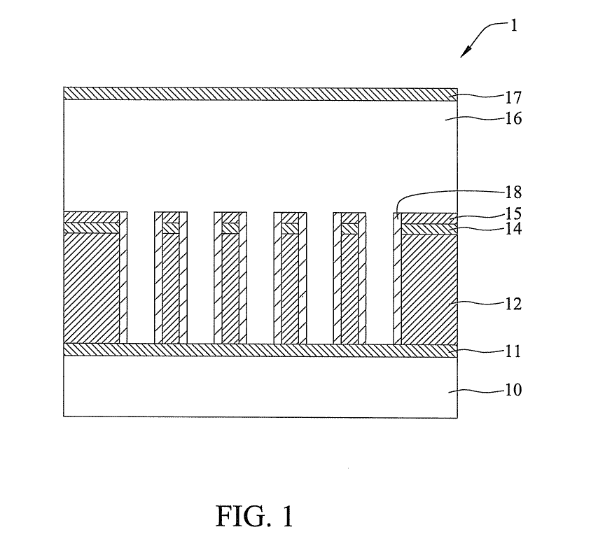

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

The present invention provides a vertical transistor having a thickness that controls a distance of electrodes. The vertical transistor of the present invention may be applied to various industries, such as semiconductor photo-electric industry, flexible electronic application industry, plastic IC industry, illuminating apparatus industry, flat panel display industry and TV industry. Particularly, the vertical transistor of the present invention may be applied to a full-color organic light-emitting display, back-light module of a cellular phone, flexible electronic product, flexible IC, car panel and flat panel TV.

### The First Embodiment

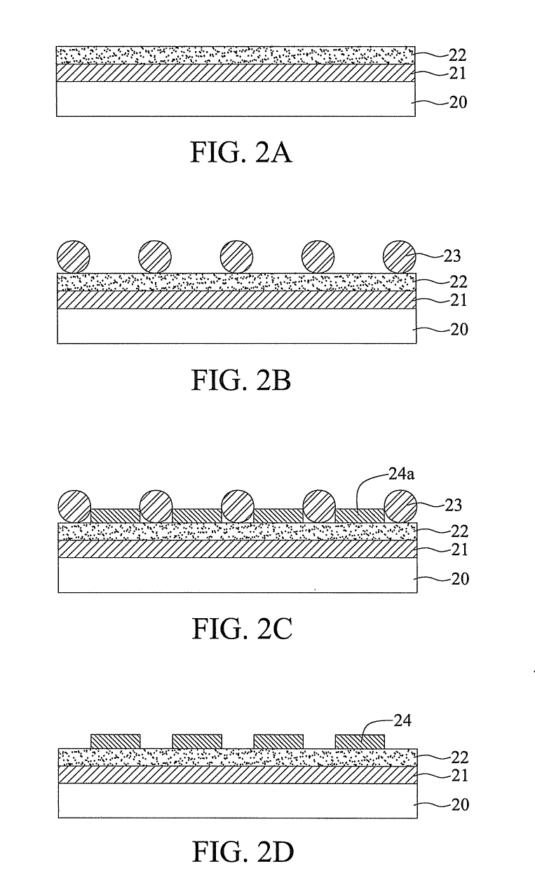

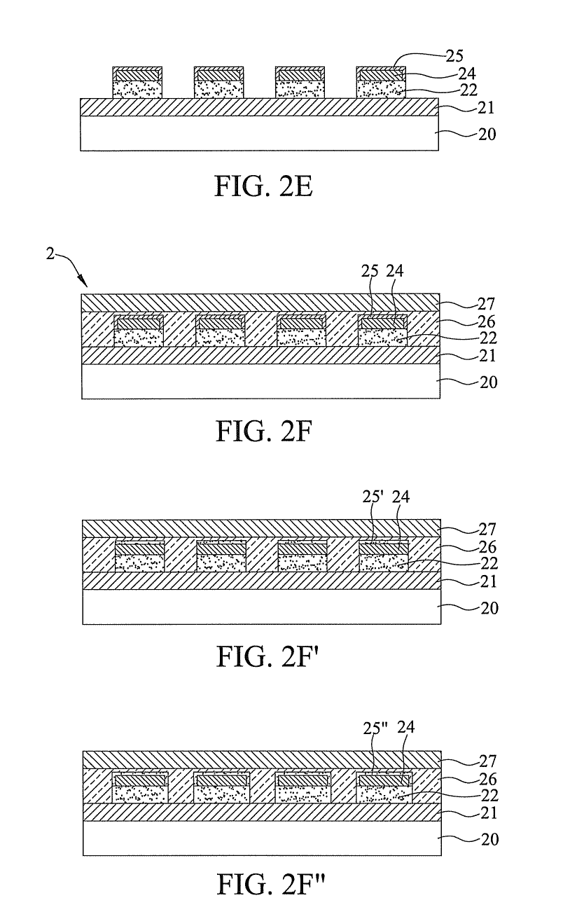

Please refer to FIGS. 2A-2F, which provide a method of fabricating an organic vertical transistor 2 having a vertical structure.

As shown in FIG. 2A, a substrate 20 is provided, and a first electrode 21 that serves as an emitter (E) or a source electrode and a first insulation layer 22 that has a thickness greater than 50 nm and no more than 300 nm are formed on the substrate 20 sequentially. In the first embodiment, the substrate 20 may be a transparent conductive glass or comprise a flexible material, such that the substrate 20 may be integrated with an organic light-emitting component effectively; the first electrode 21 may comprise indium-sin oxide (ITO); and the first insulation layer 22 may comprise a poly (4-vinyl phenol) (PVP), so as to reduce material cost. In the first embodiment, the thickness of the first insulation layer 22 may be 60 nm or 200 nm.

In the aforesaid method, the formation of the first electrode 21 and the first insulation layer 22 are conventional methods, and thus further description hereby are omitted. When forming the first insulation layer 22 on the substrate 20, the PVP polymer may comprise poly melamine-co-formaldehyde methylated that works as a cross-linking agent.

As shown in FIG. 2B, a pattern process is performed. The substrate 20 is immersed in 0.8 wt % polystyrene (PS) ethanol solution, to form on the first insulation layer 22 a plurality of balls 23 spaced apart at intervals and acting as an evaporation mask. The balls 23 have a diameter between 100 nm and 200 nm. In an embodiment, the balls 23 have a diameter of 200 nm.

As shown in FIG. 2C, after the substrate 20 is dried, a metal layer 24a having a thickness of 40 nm is evaporated and formed on the intervals at which the balls 23 are spaced apart a portion of the first insulation layer 22. In the first embodiment, the metal layer 24a may comprise aluminum.

As shown in FIG. 2D, the balls 23 are removed through the use of a 3M tape or a supersonic cleaner. The pattern process is thus completed to allow the metal layer 24a to form a grid electrode (grid) 24. In the present invention, the pattern process is performed to form the patterned grid electrode 24 on the first insulation layer 22.

As shown in FIG. 2E, by using the grid electrode 24 as a mask, a portion of the first insulation layer 22 where the grid electrode 24 is not formed is removed, such that a portion of the first electrode 21 is exposed. If the portion of the first insulation layer 22 where the grid electrode 24 is not formed is removed by an oxygen plasma, an oxide (Al₂O₃) may be formed on a surface of the grid electrode 24 to form a second insulation layer 25 due to the oxygen plasma effect, as shown in FIG. 2E.

As shown in FIG. 2F, a semiconductor layer 26 is formed on the grid electrode 24 and the first electrode 21 by a spin coating process, and then a second electrode 27 that serves as a collector (C) is evaporated and formed on the semiconductor layer 26. In the first embodiment, the semiconductor layer 26 may comprise poly (3-hexylthiophene) (P3HT), and the second electrode 27 may comprise aluminum.

As shown in FIG. 2F′, a second insulation layer 25′ is formed by another process. After the metal layer 24a is formed, the second insulation layer 25′ is formed on the metal layer 24a by an evaporation process, to reduce the leakage current between the collector and the grid electrode 24, and then the balls 23 are removed. Alternatively, as shown in FIG. 2F″ a second insulation layer 25″ may be electroplated and formed on the grid electrode 24 after the balls 23 are removed.

The second insulation layer 25″ that is formed by an electroplating process, the second insulation layer 25′ that is formed by the evaporated process, and the oxide (Al₂O₃) are different materials. However, the second insulation layers 25, 25′ and 25″ may be formed on demands. For example, the first insulation layer 22 and the second insulation layers 25, 25′ and 25″ may include the same material.

In the present invention, the balls 23 are used as a mask to form a space for the grid electrode 24 to be disposed in without a hole forming process that uses a lithography etching technique.

### The Second Embodiment

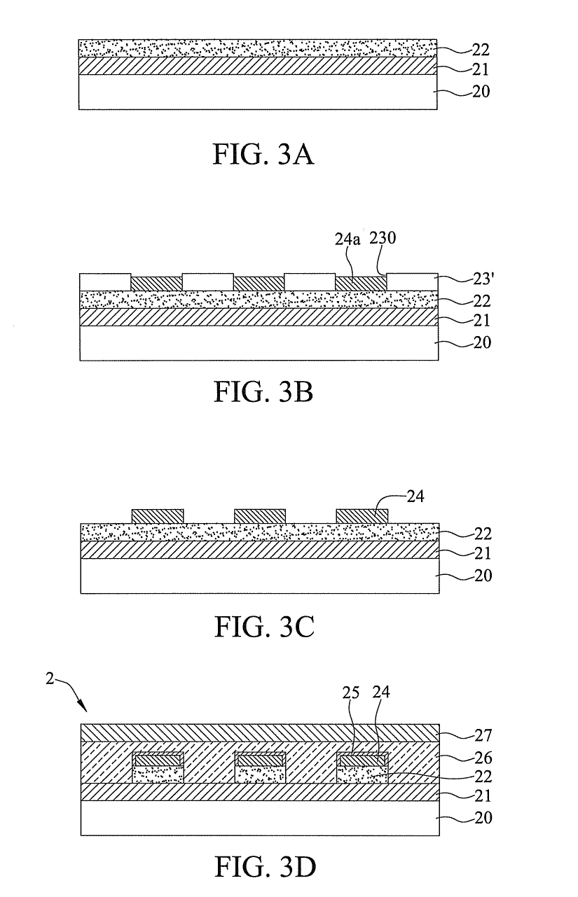

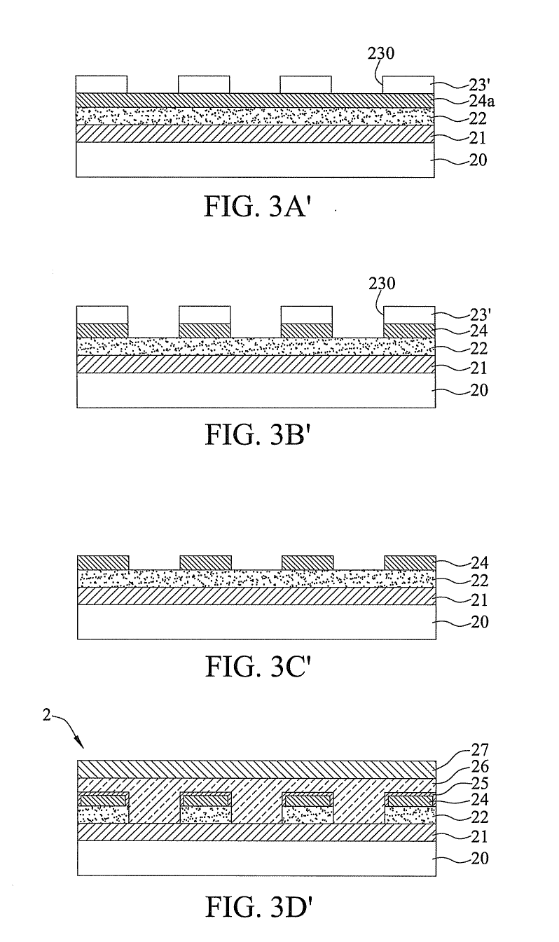

As shown in FIGS. 3A-3D, another method of fabricating a vertical transistor 2 is provided. The second embodiment is similar to the first embodiment except the formation of the mask. Therefore, the similar fabrication steps are hereby omitted, and only the different part is described in the following paragraphs.

As shown in FIG. 3A, the substrate 20 is provided, and the first electrode 21 and the first insulation layer 22 are formed on the substrate 20 sequentially.

As shown in FIG. 3B, a pattern process is performed. A resist 23′ that serves as a mask is spun and covered on the first insulation layer 22, and a plurality of holes 230 are formed on the resist layer 23′ by an imprinting process so as to expose a portion of the first insulation layer 22. Each of the holes 230 has a width of 200 nm. Then the metal layer 24a is formed on the exposed portion of the first insulation layer 22 by an electroplating or evaporation process.

As shown in FIG. 3C, the resist layer 23′ is removed, and the pattern process is completed to allow the metal layer 24a to act as the grid electrode 24.

As shown in FIG. 3D, another portion of the first insulation layer 22 on which the grid electrode 24 is not formed is removed by oxide plasma, so as to expose a portion of the first electrode 21, and form the second insulation layer 25 on the grid electrode 24. Then, the semiconductor layer 26 and the second electrode 27 are formed sequentially.

FIG. 3A′-3D′ show the use of the resist layer. As shown in FIG. 3A′, the metal layer 24a is formed on the first insulation layer 22, and then a resist layer 23′ is formed on the metal layer 24a, wherein the resist layer 23′ has a plurality of holes 230 for exposing a portion of the metal layer 24a. As shown in FIG. 3B′, the metal layer 24a in the holes 230 is etched and removed, to form the grid electrode 24. As shown in FIG. 3C′, the resist layer 23′ is removed, and the pattern process is completed. As shown in FIG. 3D′, a portion of the first insulation layer 22 on which the grid electrode 24 is not formed is removed by oxide plasma, so as to expose a portion of the first electrode 21 and form the second insulation layer 25 on the grid electrode 24. The semiconductor layer 26 and the second electrode 27 are then formed sequentially.

### The Third Embodiment

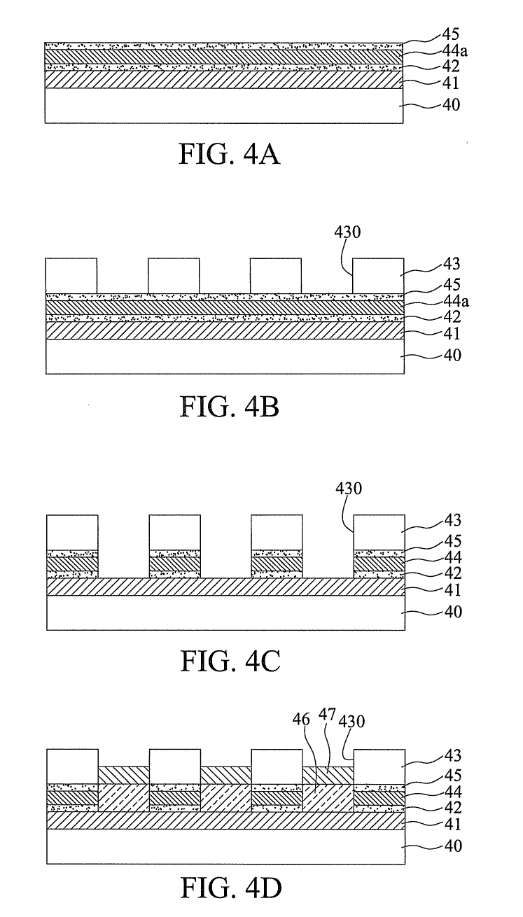

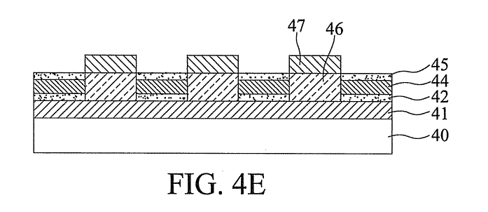

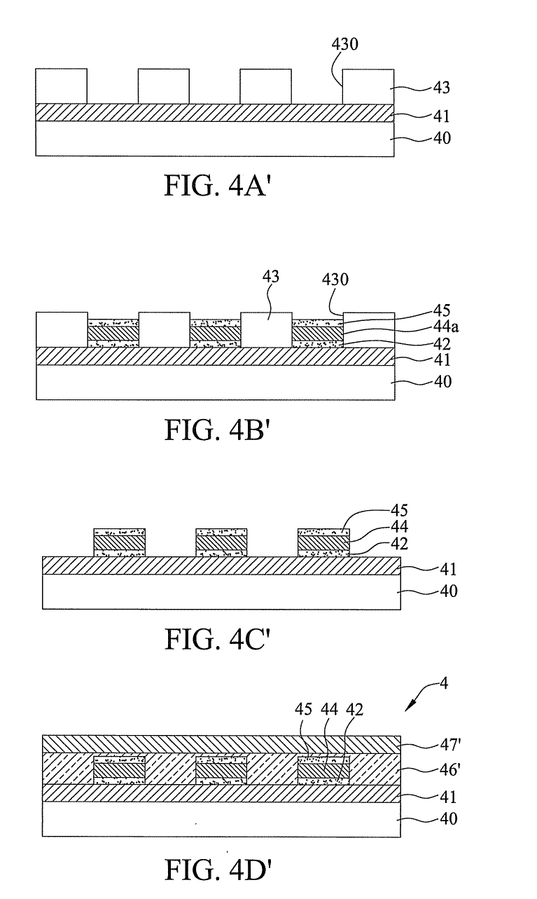

Please refer to FIGS. 4A-4E, which illustrate another method of fabricating an organic vertical transistor having a vertical structure. The third embodiment provides the same structure as the first and second embodiments, but provides a different fabrication method from the first and second embodiments.

As shown in FIG. 4A, a substrate 40 is formed, a first electrode 41 is formed on the substrate 40, and a first insulation layer 42, a metal layer 44a, and a second insulation layer 45 are formed on the first electrode 41 sequentially. In the third embodiment, the second insulation layer 45 includes oxide that serves as a buffer layer, and the first insulation layer 42 and the second insulation layer 45 may include the same material.

As shown in FIG. 4B, a pattern process is performed on the first insulation layer 42, the metal layer 44a and the second insulation layer 45. Accordingly, a resist layer 43 is formed on the second insulation layer 45, and a plurality of holes 430 are formed on the resist layer 43 by an imprinting process or a photolithography process, so as to expose a portion of the second insulation layer 45.

As shown in FIG. 4C, the second insulation layer 45, the metal layer 44a and the second insulation layer 45 in the holes 430 are removed by a reactive ion etch (RIE) process or a wet etching process, so as to expose a portion of the first electrode 41.

As shown in FIG. 4D, a semiconductor layer 46 is formed on the exposed portion of the first electrode 41, the semiconductor layer 46 is greater in thickness than the grid electrode 44, and the second electrode 47 is formed on the semiconductor layer 46 to allow the second electrode 47 not to be formed over the grid electrode 44. In other words, the second electrode 47 does not contact the grid electrode 44.

As shown in FIG. 4E, the resist layer 43 is removed. However, the resist layer 43 may be left intact to be used as an insulation layer.

Please refer to FIGS. 4A′-4D′, which illustrate a variant of a method of fabricating a vertical transistor 4 of the third embodiment according to the present invention. As shown in FIG. 4A′, the substrate 40 is provided, the first electrode 41 is formed on the substrate 40, and a pattern process is then performed, in which the resist layer 43 is formed on the first electrode 41, and the resist layer 43 has a plurality of holes 430 for exposing a portion of the first electrode 41.

As shown in FIG. 4B′, the first insulation layer 42, the metal layer 44a and the second insulation layer 45 are formed in the holes 430 sequentially.

As shown in FIG. 4C′, the resist layer 43 is removed, and the pattern process is completed, so as to form the grid electrode 44. As shown in FIG. 4D′, the semiconductor layer 46′ and the second electrode 47′ are formed sequentially.

The first, second and third embodiments provide the vertical transistor 2, 4, which includes the substrate 20, 40, the first electrode 21, 41 formed on the substrate 20, 40, the first insulation layer 22, 42 formed on the first electrode 21, 41 and with a portion of the first electrode 21, 41 exposed from the first insulation layer 22,42, the grid electrode 24, 44 formed on the first insulation layer 22, 42, the semiconductor layer 26, 46′ formed on the first electrode 21, 41 and the grid electrode 24, 44, and the second electrode 27, 47′ formed on the semiconductor layer 21, 41.

The vertical transistor 2, 4 may further include the second insulation layer 25, 45. In the embodiments shown in FIGS. 2F, 3D, 3D′ and 4D′, the second insulation layer 25, 45 is formed between the grid electrode 24, 44 and the semiconductor layer 26, 46′. Specifically, the second insulation layer 25 shown in FIG. 2F encloses the grid electrode 24, the second insulation layer 45 shown in FIG. 4D′ is formed on the grid electrode 44 only, and the first insulation layer 22, 42 and the second insulation layer 25, 25′, 25″, 45 may include the same material.

The second electrode 47 is positioned not in correspondence with the grid electrode 44, as shown in FIG. 4E.

### The Fourth Embodiment

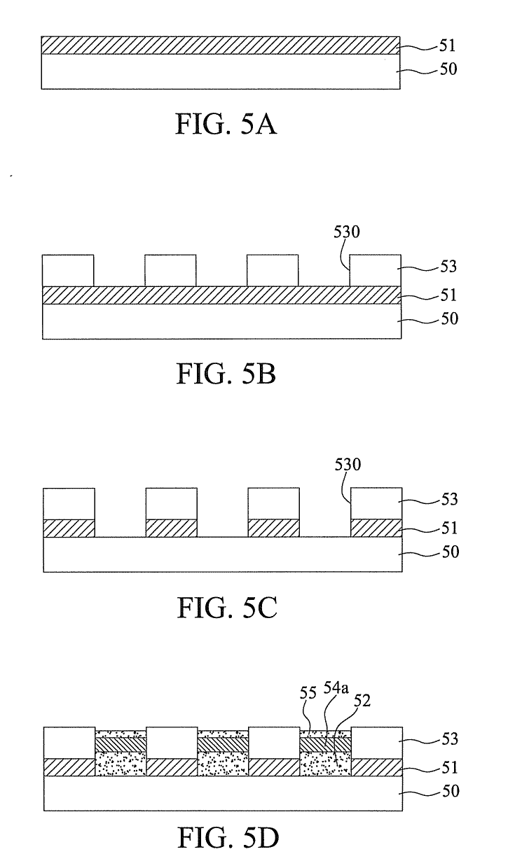

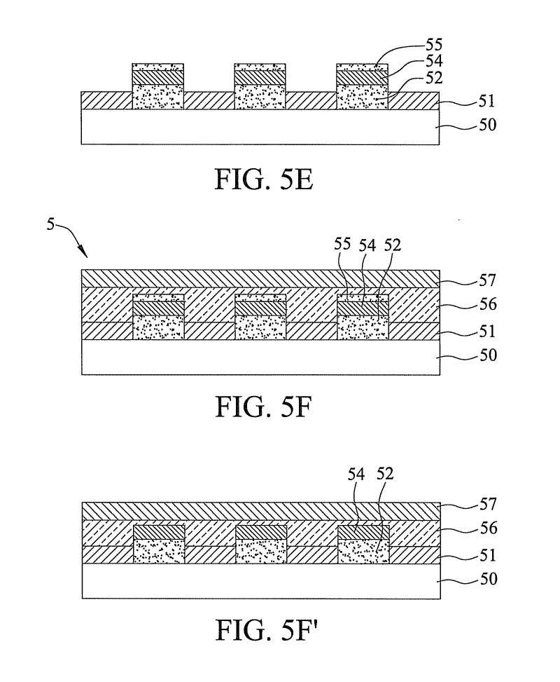

FIGS. 5A-5F illustrate a method of fabricating an organic vertical transistor 5 that has a vertical structure. The fourth embodiment differs from the first, second and third embodiments in the structure of the first electrode.

As shown in FIG. 5A, a substrate 50 is provided, and a first electrode 51 is formed on the substrate 50.

As shown in FIG. 5B, a pattern process is performed on the first electrode 51. The resist layer 53 is formed on the first electrode 51, and a plurality of holes 530 are formed on the resist layer 53 by an imprinting process, so as to expose a portion of the first electrode 51.

As shown in FIG. 5C, the first electrode 51 in the holes 530 is etched and removed, so as to expose a portion of a surface of the substrate 50.

As shown in FIG. 5D, a first insulation layer 52, a metal layer 54a and a second insulation layer 55 are formed on the exposed portion of the surface of the substrate 50 sequentially, and the first insulation layer 52 is greater in thickness than the first electrode 51 to allow the first electrode 51 not to be placed under and contact the metal layer 54a.

As shown in FIG. 5E, the resist layer 53 is removed, and the pattern process is completed to allow the metal layer 54a to act as the grid electrode 54. Therefore, since the first electrode 51 is positioned not in correspondence with the grid electrode 54, the leakage current is reduced effectively.

As shown in FIG. 5F, a semiconductor layer 56 is formed on the grid electrode 54, the second insulation layer 55 and the first electrode 51, and the second electrode 57 is formed on the semiconductor layer 56. Alternatively, as shown in FIG. 5F′ the second insulation layer 55 may be not formed.

According to the fourth embodiment, the present invention also provides a vertical transistor 5, which includes the substrate 50, the first electrode 51 formed on the substrate 50 with a portion of a surface of the substrate 50 exposed from the first electrode 51, the first insulation layer 52 formed on the exposed portion of the surface of the substrate 50 and being greater in thickness than the first electrode 51, the grid electrode 54 formed on the first insulation layer 52, the semiconductor layer 56 formed on the grid electrode 54 and the first electrode 51, and the second electrode 57 formed on the semiconductor layer 56.

In the embodiment shown in FIG. 5F, the vertical transistor 5 may further include a second insulation layer 55 formed between the grid electrode 54 and the semiconductor layer 56.

### The Fifth Embodiment

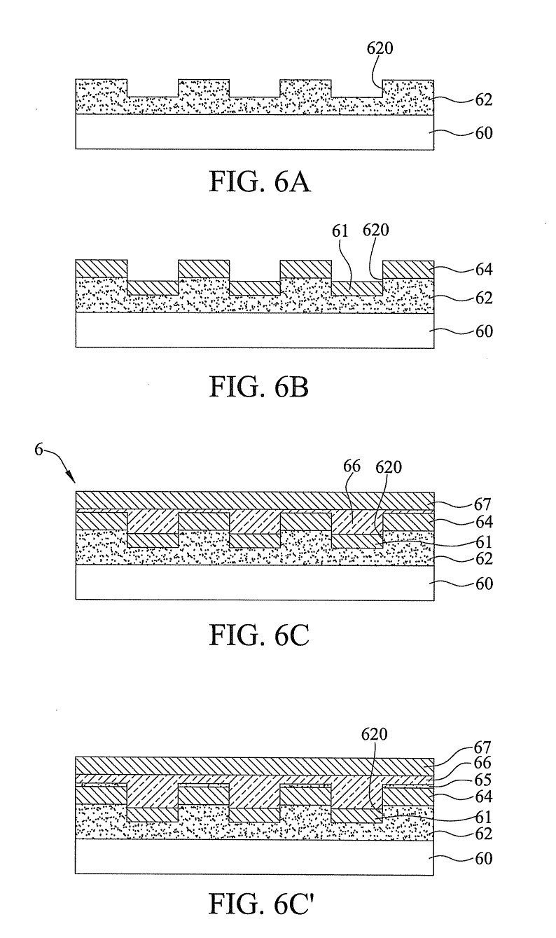

FIGS. 6A-6C illustrate another method of fabricating an organic vertical transistor 6 having a vertical structure. The fifth embodiment differs from the fourth embodiment in the structure of the first insulation layer.

As shown in FIG. 6A, a substrate 60 is provided, a first insulation layer 62 is formed on the substrate 60, and a plurality of grooves 620 are formed by an imprinting process on the first insulation layer 62. In the fifth embodiment, the first insulation layer 62 includes the same material as the resist layer of the aforesaid embodiments.

As shown in FIG. 6B, a metal layer is formed on the first insulation layer 62, wherein the metal layer in the grooves 620 is used as the first electrode 61, and the metal layer that is positioned not in correspondence with the grooves 620 is used as the grid electrode 64. Accordingly, the grid electrode 64 is disposed on a top surface of the first insulation layer 62 that does not include the grooves 620, and the first electrode 61 has a height less than a depth of the grooves 620, such that the first electrode 61 is positioned not in correspondence with and does not contact the grid electrode 64.

As shown in FIG. 6C, a semiconductor layer 66 is formed on the first electrode 61 and the grid electrode 64, and a second electrode 67 is formed on the semiconductor layer 66. However, as shown in FIG. 6C′, prior to covering the semiconductor layer 66, the second insulation layer 65 may be formed on the grid electrode 64 on demands.

According to the fifth embodiment, the present invention further provides a vertical transistor 6, which includes the substrate 60, the first insulation layer 62 formed on the substrate 60 and having a plurality of grooves 620, the first electrode 61 formed in the grooves 620 and having a height less than a depth of the grooves 620, the grid electrode 64 formed on the first insulation layer 62 and positioned not in correspondence with the first electrode 61, the semiconductor layer 66 formed on the grid electrode 64 and the first electrode 61, and the second electrode 67 formed on the semiconductor layer 66.

In the embodiment shown in FIG. 6C′, the vertical transistor 6 further includes the second insulation layer 65 formed between the grid electrode 64 and the semiconductor layer 66.

In sum, with the design of the insulation layer, the vertical transistor of the present invention has a low operation voltage (less than two volts) and a high on/off ratio (about 10⁴, which is obtained by dividing a collector current density when the grid electrode voltage is −1V by another collector current density when the grid electrode voltage is 2.3V), and has an even higher on/off ratio through the use of a thicker PVP. For example, when a PVP having a thickness being 210 nm is used, components have an on/off ratio as high as 3×10⁵. In the vertical transistor shown in FIG. 2F, the thickness of the first insulation layer is 60 nm, and the on/off ratio is 10,775. As the thickness of the first insulation layer is 200 nm, the on/off ratio is 260,000. Due to the design of a thicker first insulation layer, the present invention reverses the teaching of the prior art that “the insulation layers have worse performance while being thicker.” As the first insulation layer is 50-300 nm, the efficiency bottleneck of the on/off ratio is broken and the low operating voltage (less than two volts) and high on/off ratio may be kept. Due to the design of the insulation layer, there is not need to perform a pattern process on a semiconductor layer, and the semiconductor layer does not have damaged characteristics in the present invention. Compared with the prior art, the present invention increases the yield rate of the vertical transistors.

Since the present invention only needs to fabricate a single semiconductor layer, the present invention reduces the fabrication cost and decreases the distance of electrodes, as compared with the prior art which needs to fabricate two semiconductor layers.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A vertical transistor, comprising:
a substrate;
a first electrode formed on the substrate;
a first insulation layer formed on the first electrode, with a portion of the first electrode exposed from the first insulation layer, and having a thickness greater than 50 nm and no more than 300 nm;
a grid electrode formed on the first insulation layer;
a semiconductor layer formed on the first electrode; and
a second electrode formed on the semiconductor layer.

2. The vertical transistor of claim 1, further comprising a second insulation layer, wherein the semiconductor layer is further formed on the grid electrode so as for the second insulation layer to be is formed between the grid electrode and the semiconductor layer.

3. The vertical transistor of claim 2, wherein the first insulation layer and the second insulation layer are made of same material.

4. The vertical transistor of claim 1, further comprising a second insulation layer formed on the grid electrode.

5. The vertical transistor of claim 1, wherein the second electrode is positioned not in correspondence with the grid electrode.

6. A vertical transistor, comprising:
a substrate;
a first electrode formed on the substrate with a portion of a surface of the substrate exposed from the first electrode;
a first insulation layer formed on the portion of the surface of the substrate and being greater in thickness than the first electrode;
a grid electrode formed on the first insulation layer;
a semiconductor layer formed on the grid electrode and the first electrode; and
a second electrode formed on the semiconductor layer.

7. The vertical transistor of claim 6, further comprising a second insulation layer formed between the grid electrode and the semiconductor layer.

8. A vertical transistor, comprising:
a substrate;
a first insulation layer formed on the substrate and having a plurality of grooves formed thereon;
a first electrode formed in the grooves and having a height less than a depth of the grooves;
a grid electrode formed on the first insulation layer and positioned not in correspondence with the first electrode;
a semiconductor layer formed on the grid electrode and the first electrode; and
a second electrode formed on the semiconductor layer.

9. The vertical transistor of claim 8, further comprising a second insulation layer formed between the grid electrode and the semiconductor layer.

10. A method of fabricating a vertical transistor, comprising the steps of:
providing a substrate;
forming on the substrate a first electrode and a first insulation layer sequentially;
forming a patterned grid electrode on the first insulation layer;
removing a portion of the first insulation layer on which the grid electrode is not formed by using the grid electrode as a mask, to expose a portion of the first electrode;
covering the grid electrode and the first electrode with a semiconductor layer; and
forming a second electrode on the semiconductor layer.

11. The method of claim 10, wherein the step of forming the patterned grid electrode comprises:
forming on the first insulation layer a plurality of balls spaced apart at intervals;
forming a metal layer on the intervals at which the balls are spaced apart on the first insulation layer; and
removing the balls to allow the metal layer to form the grid electrode.

12. The method of claim 10, wherein the step of forming the patterned grid electrode comprises:
forming on the first insulation layer a resist layer having a plurality of holes that expose a portion of the first insulation layer;
forming a metal layer on the portion of the first insulation layer; and
removing the resist layer to allow the metal layer to form the grid electrode.

13. The method of claim 10, wherein the step of forming the patterned grid electrode comprises:
forming a metal layer on the first insulation layer;
forming on the metal layer a resist layer having a plurality of holes that expose a portion of the metal layer;
removing the portion of the metal layer; and
removing the resist layer to allow the remaining metal layer to form the grid electrode.

14. The method of claim 10, further comprising forming a second insulation layer on the grid electrode.

15. A method of fabricating a vertical transistor, comprising the steps of:
providing a substrate;
forming a first electrode on the substrate;
forming on the first electrode a first insulation layer, a metal layer, and a second insulation layer, and pattering the first insulation layer, the metal layer, and the second insulation layer, to allow the metal layer to form a grid electrode and expose a portion of the first electrode;
forming on the portion of the first electrode a semiconductor layer that being greater in thickness than the grid electrode; and
forming on the semiconductor layer a second electrode that is positioned not in correspondence with the grid electrode.

16. A method of fabricating a vertical transistor, comprising the steps of:
providing a substrate;
forming a first electrode on the substrate;
forming on the first electrode a resist layer having a plurality of holes for exposing a portion of the first electrode;
forming in the holes a first insulation layer and a metal layer sequentially;
removing the resist layer to allow the metal layer to form a grid electrode;
forming a semiconductor layer on the grid electrode and the first electrode; and
forming a second electrode on the semiconductor layer.

17. The method of claim 16, further comprising prior to forming the first insulation layer, removing the portion of the first electrode to expose a portion of a surface of the substrate, wherein the first insulation layer and the metal layer are formed sequentially on the portion of the surface of the substrate, and the first insulation layer greater in thickness than the first electrode.

18. The method of claim 16, further comprising prior to removing the resist layer, forming a second insulation layer on the metal layer.

19. A method of fabricating a vertical transistor, comprising the steps of:
providing a substrate;
forming on the substrate a first insulation layer having a plurality of grooves;
forming a metal layer on the first insulation layer, wherein the metal layer in the grooves serves as a first electrode, while the metal layer not in the grooves serves as a grid electrode, and the first electrode has a height less than a depth of the grooves;
forming a semiconductor layer on the first electrode and the grid electrode; and
forming a second electrode on the semiconductor layer.

20. The method of claim 19, further comprising prior to forming the semiconductor layer, forming a second insulation layer on the grid electrode.
